(19) United States
(12) Patent Application Publication
(10) Pub. No.: US 2006/0102964 A1
(43) Pub. Date: May 18, 2006

(54) Passive device and method for forming the same

(75) Inventor: Chien-Chao Huang, Hsin-Chu City (TW)

Correspondence Address: DUANE MORRIS, LLP;IP DEPARTMENT, 30 SOUTH 17TH STREET, PHILADELPHIA, PA, 19103-4196, US

(73) Assignee: Taiwan Semiconductor Manufacturing Co., Ltd.

(21) Appl. No.: 11/112,655

(22) Filed: Apr. 22, 2005

Related U.S. Application Data
(63) Continuation of application No. 10/988,898, filed on Nov. 15, 2004.

(51) Int. Cl. H01L 29/76

(52) U.S. Cl. 257/388

(57) ABSTRACT

An integrated circuit includes an active device, having a metal gate electrode, disposed on a substrate. A passive device, made of a semiconductor material, is disposed adjacent to the active device above the substrate. A dielectric layer is interposed between the passive device and the substrate for separating the same.

### BACKGROUND

The present invention relates generally to integrated circuit designs, and more particularly to a passive device formed on top of an active device.

The geometric features of circuit elements, such as resistors, transistors, and fuses, in integrated circuits (ICs) shrink with each technological generation. The gate dielectric of metal-oxide-semiconductor (MOS) transistors in an IC has become very thin. Doping from a polycrystalline silicon (poly-silicon) gate electrode can, at succeeding process temperatures, easily penetrate the thin gate dielectric and change the electrical characteristics of the MOS channel region thereunder. In addition, due to the thin gate dielectric, the depletion caused by the doped poly-silicon gate electrode also alters the characteristics of the channel region in an undesirable way. To avoid these problems, there is a trend to replace the conventional poly-silicon gate electrode with metal materials. Since a metal gate electrode is not doped with ions, the problems of dopants penetration and poly depletion can be eliminated.

Conventionally, the poly-silicon layer that forms the gate electrode is also used in the formation of resistors and fuses. This causes a challenge to the new trend of IC fabrication, because the metal layer that forms the metal gate electrode is not an appropriate material for forming the resistors and fuses. The metal layer has too low a resistivity to serve as a resistor, and generates too little heat, which is necessary for “blowing,” to serve as a fuse. Thus, the metal gate electrode, resistor, and fuse can not be formed concurrently, as the conventional art teaches.

Desirable in the art of integrated circuit designs are a semiconductor structure and its fabrication method that provide devices, such as resistors and fuses, in an IC in which transistors do not use poly-silicon as the material for their gate electrodes.

### SUMMARY

In view of the foregoing, the following provides an integrated circuit having a passive device atop an active device and a method for forming the same. In one embodiment, the integrated circuit includes an active device, having a metal gate electrode, disposed on a substrate. A passive device, made of a semiconductor material, is disposed adjacent to the active device above the substrate. A dielectric layer is interposed between the passive device and the substrate for separating the same.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows a conventional poly-silicon resistor.

FIG. 2 shows a conventional poly-silicon fuse.

FIGS. 3A to 3D present a series of partial sectional views of semiconductor structures illustrating the processing steps for fabricating a passive device atop an active device, in accordance with one embodiment of the present invention.

FIG. 4 presents a flow chart illustrating the processing steps, in accordance with one embodiment of the present invention.

FIGS. 5A to 5D present a series of partial sectional views of semiconductor structures illustrating the processing steps for fabricating a passive device adjacent to an active device, in accordance with one embodiment of the present invention.

### DESCRIPTION

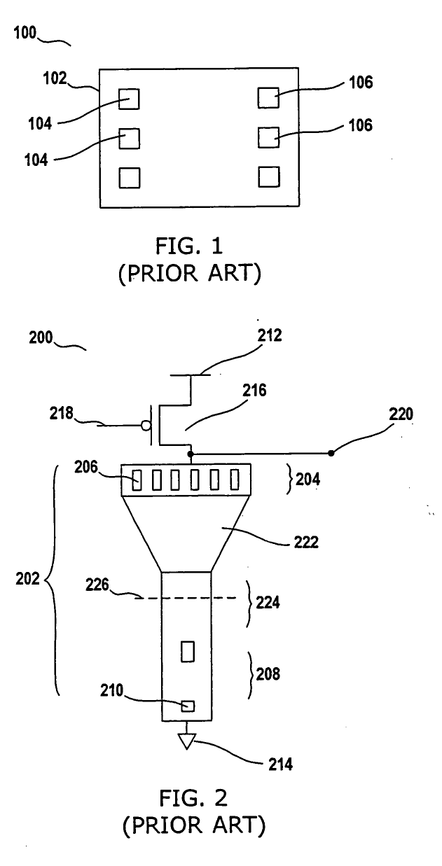

FIG. 1 illustrate a layout 100 of a conventional poly-silicon resistor 102 with a plurality of positive end contacts 104 and a plurality of negative end contacts 106. The end contacts 104 and 106 are openings in any overlying dielectric layer to allow electrical contact to the poly-silicon layer that is covered by one or more dielectric layers. The poly-silicon layer is preferably doped with ions to adjust its resistivity. The poly-silicon resistor 102, with a pre-determined resistivity and shape, has a circuit functional resistance. The poly-silicon material that is used to construct the resistor 102 is valued because of its high resistivity. Metal can not properly serve as a resistor, for its relatively low resistivity, with respect to poly-silicon.

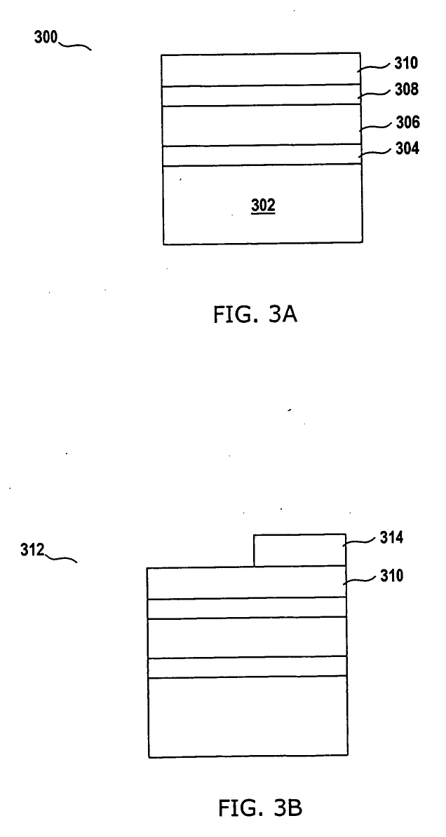

In FIG. 2, a layout 200 illustrates a poly-silicon fuse 202 having an anode block 204 with multiple contacts 206, and a cathode block 208 with at least one contact 210. The fuse is operative in a circuit with a power supply connection 212 and a ground connection 214. A select transistor 216 is switched by a select signal at a gate 218, and has an output 220. The poly fuse 202 further includes a taper section 222 between the anode block 204 and a neck section 224, which is connected to the cathode block 208. When a designed low voltage is applied between the anode block 204 and the cathode block 208, sufficient current flows through the poly-silicon fuse 202 and generates enough heat, due to its relatively high resistivity, to “blow” it. When the select transistor 216 is switched on by a select signal at the gate 218, the signal level at the output 220 is at a low logic state for an “unblown” fuse, and is at a high logic state for a “blown” fuse. If the fuse was constructed of a metal layer, the fuse would have been very difficult to “blow” because the low resistivity of the metal would allow a large current to flow therethrough, without generating sufficient heat that is required to “blow” itself.

As discussed above, metal can not serve well as a resistor or fuse. Semiconductor materials, such as poly-silicon, germanium and silicon/germanium alloys, are still the ideal candidates for devices, such as resistors and fuses. However, as discussed in the background, there is trend of using metal instead of poly-silicon as the material for the gate electrode of a MOS transistor. Conventionally, the resistors and fuses can be formed alongside the gate electrode without demanding additional process steps, due to their common choice of material, i.e., poly-silicon. When the metal gate electrode is used, it is no longer made of the same material as those for resistors and fuses, a new fabrication process is needed to integrate them both in an IC.

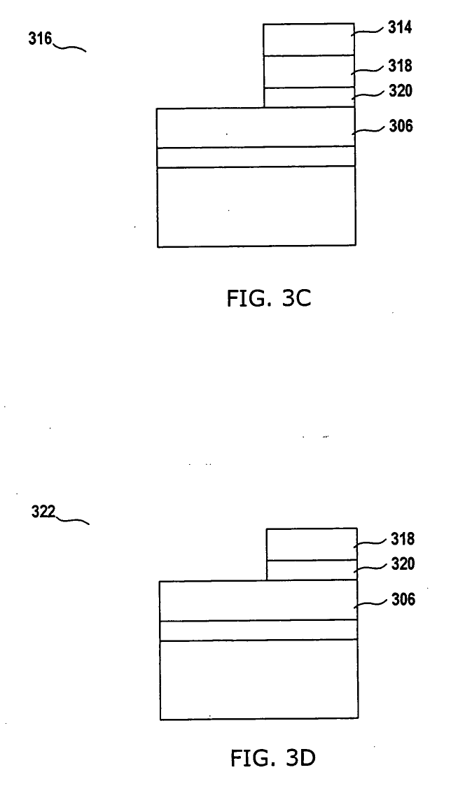

FIGS. 3A through 3D illustrate a series of a partial, sectional views of an IC in which a passive device, such as a resistor or fuse, is formed atop an active device, such as a MOS transistor having a gate electrode made of metal.

In FIG. 3A, a cross section 300 illustrates a layer structure prior to patterning. A semiconductor substrate 302 is covered by a high-k dielectric layer 304 that serves as a gate dielectric for a metal-oxide-semiconductor (MOS) transistor on the semiconductor substrate 302. A metal layer 306 is deposited on the high-K dielectric layer 304 to serve as a metal gate electrode for the MOS transistor. The metal layer 304 is made of a material, for example, including refractory metal, silicide, W, Al, AlCu, Ti, TiSi₂, Co, CoSi₂, NiSi, TiN, TiW, or TaN. A dielectric layer 308 is deposited on the metal layer 306 to separate the metal layer 306 from a succeeding deposit of a semiconductor layer 310. In order to properly separate the semiconductor layer 310 from the metal layer 306, the dielectric layer 308 is suggested to have a thickness between 20A and 2000A. The dielectric layer 308 is made of a material, for example, including silicon oxide, silicon nitride, silicon carbon, silicon carbide, HfO2, HfSiON, nitrogen containing silicon oxide, or any material having a dielectric constant greater than 3. The semiconductor layer 310 is made of a material, for example, including silicon, germanium, or silicon/germanium alloy. The semiconductor layer 310 is doped with ions of various types and dosages, depending on its desired resistivity. The semiconductor layer 310 is useful in the construction of passive devices, such as the resistor in FIG. 1 and the fuse in FIG. 2, that will be shown in the following process steps.

In FIG. 3B, a cross section 312 illustrates a stage in the construction of the passive device. A photoresist layer is deposited on the semiconductor layer 310 and patterned to create a photoresist island 314. This can be done by a photolithography process. A layer of photoresist is blanketly applied over the semiconductor layer 310. This photoresist layer is then exposed to light through a mask, which has predefined patterns. The areas of the photoresist layer exposed to light are made either soluble or insoluble in a specific developer. The patterns of the mask is, therefore, transferred to the photoresist layer, and, in this embodiment, provides the photoresist island 314.

In FIG. 3C, a cross section 316 illustrates a further stage in the construction of the passive device. The photoresist island 314 masks the etching of the existing semiconductor layer 310 (see FIG. 3B) to create a semiconductor island 318, and further masks the etching of the existing dielectric layer 308 (see FIG. 3B) to create a dielectric island 320. Parts of the metal layer 306 are exposed around the semiconductor island 318 stacked on top of the dielectric island 320. The etching can be done by a dry etching or wet etching process. Proper types of etching chemical agents can be selected to adjust the etching rates of the two. In one embodiment, the metal layer 306 serves as a etch stop layer for controlling the end point of the etching of the dielectric layer 308.

In FIG. 3D, a cross section 322 illustrates yet a further stage in the construction of a fuse. The photoresist island is then removed. The semiconductor island 318 remains on the dielectric island 320, which remains on the metal layer 306. The semiconductor island 318 is electrically isolated from the metal layer 306 by the dielectric island 320. The resistivity of the semiconductor island 318 is high enough such that it can serve as a resistor or a fuse that can be “blown” by a current, from a low voltage source. The semiconductor island 318 is formed atop the dielectric island 320, so it is named a passive device. The passive device partially and vertically overlaps the metal layer 306, which severs as the gate electrode of the active device, i.e., the MOS transistor, in this embodiment. A part of the metal layer is uncovered by the semiconductor island 318, so that it can be connected to other interconnections in an IC. This integrates the fabrication processes for forming the active device and the passive device, without occupying additional layout areas.

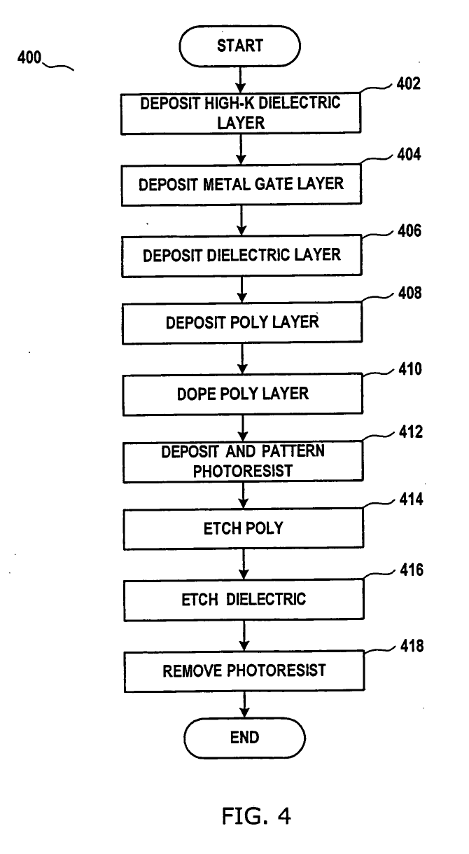

FIG. 4 presents a flow chart 400 illustrating the processing steps in accordance with one embodiment of the present invention. These are the process steps for the construction of a plurality of poly resistors, poly fuses, and metal gate transistors in the same IC. However, it is understood that passive devices other than resistors and fuses can be formed by the same or similar process steps, without departing the spirit of the invention. Also, the material used for the passive device can be any semiconductor material, not just limited to poly-silicon.

The process starts with a bare semiconductor substrate. In step 402, a high-k dielectric is deposited to be used as a MOS transistor gate dielectric. In step 404, a metal layer is deposited atop the high-k dielectric to be used as a MOS transistor gate electrode. The high-k dielectric is appropriate with a metal gate electrode to increase gate capacitance, since the gate dielectric is very thin. The use of a metal gate electrode is appropriate to avoid gate dopant penetration of the thin gate dielectric. The particular metal selected should not melt in the succeeding steps, such as poly deposition. The MOS transistors are completed separately. In step 406, a typical dielectric is deposited on the metal gate layer. In step 408, a poly layer is deposited to be used in the construction of resistors and fuses. In step 410, the poly layer is doped to a predetermined resistivity. In step 412, photoresist is deposited and patterned in preparation for the definition of resistor and fuse shapes. In step 414, the poly is etched using the photoresist as a mask. In step 416, the dielectric is etched using the photoresist and the poly as a mask. In step 418, the photoresist is removed. The resistors and fuses are at this point delineated. At this point, succeeding dielectric and metal interconnection layers can now be applied to complete the rest of the structure.

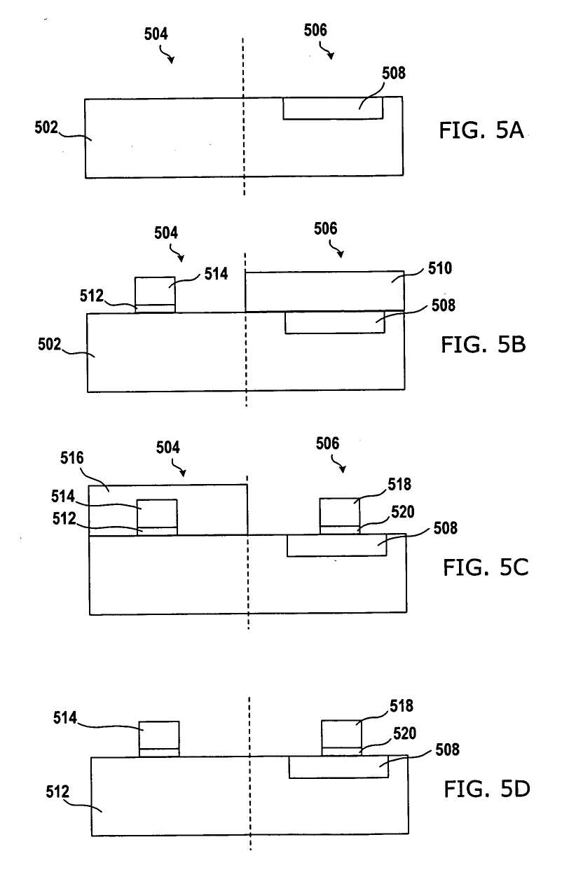

FIGS. 5A through 5D illustrate a series of a partial, sectional views of an IC in which a passive device, such as a resistor or fuse, is formed adjacent to an active device, such as a MOS transistor with a gate electrode made of metal.

In FIG. 5A, a semiconductor substrate 502, having an active region 504 for construction of an active device, and a passive region 506 for construction of a passive device, is provided. The semiconductor substrate 502 is made of a material including, but not limited to, silicon, germanium, and silicon/germanium alloy. A isolation structure 508, such as a shallow trench isolation (STI) or local oxidation of silicon (LOCOS), is formed on the semiconductor substrates 502 in the passive region 506.

In FIG. 5B, a photoresist layer 510 is formed over the passive region 506, covering the isolation structure 508. A gate dielectric layer 512 is formed atop the semiconductor substrate 502 in the active region 504. A metal gate electrode 514 is formed atop the gate dielectric layer 512. The metal gate electrode 514 and gate dielectric layer 512 stack may be constructed by performing processes of deposition followed by patterning and etching. The metal gate electrode 514 is made of a material including, but not limited to, refractory metal, silicide, W, Al, AlCu, Ti, TiSi₂, Co, CoSi₂, NiSi, TiN, TiW, or TaN.

In FIG. 5C, the photoresist layer 510, as shown in FIG. 5B, is removed. A photoresist layer 516 is formed over the active region 504, covering the metal gate electrode 514 and the gate dielectric layer 512. A passive device 518 is formed in the passive region 506, with a dielectric layer 520 interposed between the same and the isolation structure 508. The passive device 518 may be, for example, a resistor or fuse. It may be made of a semiconductor material such as, poly-silicon or silicon germanium. The dielectric layer 520 may be made of a material including, but not limited to, silicon oxide, silicon nitride, silicon carbon, silicon carbide, HfO2, HfSiON, nitrogen containing silicon oxide, or any material having a dielectric constant greater than 3. In this embodiment, it is suggested that the thickness of the dielectric layer 520 is between 20 and 2000 Angstroms.

In FIG. 5D, the photoresist layer 516, as shown in FIG. 5C, is removed. This provides an IC with an active device having a metal gate electrode 514 formed adjacent to a passive device 518 that is made of a semiconductor material. It is noteworthy that while, in this embodiment, the passive device 518 is constructed above the isolation structure 508, it may be formed directly atop the semiconductor substrate 512, as long as the dielectric layer 520 is interposed therebetween.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. An integrated circuit comprising:
an active device, having a metal gate electrode, disposed on a substrate;
a passive device, made of a semiconductor material, disposed adjacent to the active device above the substrate; and
a dielectric layer interposed between the passive device and the substrate for separating the same.

2. The integrated circuit of claim 1 wherein the active device is a MOS transistor.

3. The integrated circuit of claim 1 wherein the metal gate electrode is made of a material including refractory metal, silicide, W, Al, AlCu, Ti, TiSi₂, Co, CoSi₂, NiSi, TiN, TiW, or TaN.

4. The integrated circuit of claim 1 wherein the dielectric layer has a thickness between 20 and 2000 Angstroms.

5. The integrated circuit of claim 1 wherein the dielectric layer is made of a material including silicon oxide, silicon nitride, silicon carbon, silicon carbide, HfO2, HfSiON, nitrogen containing silicon oxide, or any material having a dielectric constant greater than 3.

6. The integrated circuit of claim 1 wherein the passive device is a poly-silicon or silicon germanium resistor.

7. The integrated circuit of claim 1 wherein the passive device is a poly-silicon or silicon germanium fuse.

8. An integrated circuit comprising:
an active device, having a metal gate electrode;
a passive device disposed above the metal gate electrode; and
a dielectric layer interposed between the metal gate electrode and the passive device for separating the passive device from being in contact with the same.

9. The integrated circuit of claim 8 wherein a part of the metal gate electrode is uncovered by the passive device.

10. The integrated circuit of claim 8 wherein the active device is a MOS transistor.

11. The integrated circuit of claim 8 wherein the metal gate electrode is made of a material including refractory metal, silicide, W, Al, AlCu, Ti, TiSi₂, Co, CoSi₂, NiSi, TiN, TiW, or TaN.

12. The integrated circuit of claim 8 wherein the dielectric layer has a thickness between 20 and 2000 Angstroms.

13. The integrated circuit of claim 8 wherein the dielectric layer is made of a material including silicon oxide, silicon nitride, silicon carbon, silicon carbide, HfO2, HfSiON, nitrogen containing silicon oxide, or any material having a dielectric constant greater than 3.

14. The integrated circuit of claim 8 wherein the passive device is a poly-silicon or silicon germanium resistor.

15. The integrated circuit of claim 8 wherein the passive device is a poly-silicon or silicon germanium fuse.

16. A method for forming a passive device, comprising:
forming a gate dielectric layer on a semiconductor substrate;
forming a metal gate electrode on the gate dielectric layer;
depositing a dielectric layer on the metal gate electrode;
depositing a semiconductor layer on the dielectric layer; and
patterning the semiconductor layer and the dielectric layer to form the passive device.

17. The method of claim 16 wherein the metal gate electrode is made of a material including refractory metal, silicide, W, Al, AlCu, Ti, TiSi₂, Co, CoSi₂, NiSi, TiN, TiW, or TaN.

18. The method of claim 16 wherein the dielectric layer is made of a material including silicon oxide, silicon nitride, silicon carbon, silicon carbide, HfO2, HfSiON, nitrogen containing silicon oxide, or any material having a dielectric constant greater than 3.

19. The method of claim 16 wherein the semiconductor layer is made of a material including silicon, germanium, or silicon/germanium alloy.

20. The method of claim 16 further comprising doping the semiconductor layer with ions before the patterning.
